(19) United States
(12) Patent Application Publication
(10) Pub. No.: US 2025/0069658 A1
(43) Pub. Date: Feb. 27, 2025

(54) Threshold Voltage Reduction in Memristive Devices

(71) Applicant: International Business Machines Corporation, Armonk, NY (US)

(72) Inventors: Ghazi Sarwat Syed, Kilchberg (CH); Vara Sudananda Prasad Jonnalagadda, Wallisellen (CH)

(21) Appl. No.: 18/237,787

(22) Filed: Aug. 24, 2023

(51) Int. Cl. G11C 16/04; G11C 8/08; G11C 16/30

(52) U.S. Cl. CPC G11C 16/04; G11C 8/08; G11C 16/30

(57) ABSTRACT

Techniques for reducing a threshold voltage of memristive devices via field effects are provided. In one aspect, a memristive device includes: a memristive material; multiple electrodes directly contacting the memristive material; and a gate terminal separated from the memristive material by an electrical insulator. The memristive device can be implemented as one of multiple memristive devices in a unit cell with a gate word line connected to the gate terminal of each of the multiple memristive devices in the unit cell. A method for operating the present memristive devices is also provided.

### FIELD OF THE INVENTION

The present invention relates to memristive devices, and more particularly, to techniques for using field effects to reduce a threshold voltage of memristive devices via an applied gate voltage.

### BACKGROUND OF THE INVENTION

Resistive memory devices (termed ‘memristive’ devices) store information based on the resistance of an active region of the device. Phase change materials are an ideal candidate for use as the active region since they can encode information based on the phase configuration, and hence resistance, of the material.

A key parameter governing the implementation of memristive memory devices is the threshold voltage. Namely, in modern multi-level memristive memory devices and analog computational memory devices, threshold voltages are non-trivial owing to the choice and large volumes of the phase change materials employed. However, large threshold voltages undesirably increase the overall power dissipation of the device.

Further, multiple access transistors, attached in series, are often required to access memristive memory devices, where the voltage distribution between the transistors ensures that no access transistor is over-driven in the state of high field and potential breakdown. However, the use of multiple access transistors increases the areal complexity (i.e., inefficiencies) of the device architecture.

Therefore, techniques that efficiently and effectively reduce the threshold voltage of phase change material-based devices such as memristive memory devices would be desirable.

### SUMMARY OF THE INVENTION

The present invention provides techniques for using field effects to reduce a threshold voltage of memristive devices via an applied gate voltage. In one aspect of the invention, a memristive device is provided. The memristive device includes: a memristive material; multiple electrodes directly contacting the memristive material; and a gate terminal separated from the memristive material by an electrical insulator.

In another aspect of the invention, a system is provided. The system includes: a unit cell having multiple memristive devices, wherein each of the multiple memristive devices includes a memristive material, multiple electrodes directly contacting the memristive material, and a gate terminal separated from the memristive material by an electrical insulator; and a gate word line connected to the gate terminal of each of the multiple memristive devices in the unit cell.

In yet another aspect of the invention, a method for operating a memristive device is provided. The method includes: applying a gate voltage to the memristive device, where the memristive device includes a memristive material, multiple electrodes directly contacting the memristive material, and a gate terminal separated from the memristive material by an electrical insulator, and where the gate voltage is applied to the gate terminal to build up charge in the memristive material, thereby lowering a threshold voltage of the memristive material via field effects.

A more complete understanding of the present invention, as well as further features and advantages of the present invention, will be obtained by reference to the following detailed description and drawings.

### BRIEF DESCRIPTION OF THE DRAWINGS

FIG. 1 is a diagram illustrating an exemplary memristive device having a gate terminal separated from a memristive material by a gate dielectric, an access transistor, a first electrode on a bottom of the memristive material, and second and third electrodes on opposite sides of the memristive material according to an embodiment of the present invention;

FIG. 2 is a diagram illustrating an exemplary methodology for fabricating a memristive device according to an embodiment of the present invention;

FIG. 3 is a diagram illustrating an exemplary memristive device having the gate terminal separated from the memristive material by the gate dielectric, the access transistor, and the first as well as the second and third electrodes on the bottom of the memristive material according to an embodiment of the present invention;

FIG. 4 is a diagram illustrating an exemplary memristive device having the gate terminal separated from the memristive material by a ferroelectric material, the access transistor, the first electrode on the bottom of the memristive material, and the second and third electrodes on opposite sides of the memristive material according to an embodiment of the present invention;

FIG. 5 is a diagram illustrating an exemplary memristive device having the gate terminal separated from a memristive material by the ferroelectric material, the access transistor, and the first, second and third electrodes on the bottom of the memristive material according to an embodiment of the present invention;

FIG. 6 is a diagram illustrating an exemplary memristive device having the gate terminal separated from the memristive material by a ferroelectric material having pre-aligned ferroelectric domains, the access transistor, and the first, second and third electrodes on the bottom of the memristive material according to an embodiment of the present invention;

FIG. 7 is a diagram illustrating an exemplary memristive device having the gate terminal separated from the memristive material by either the ferroelectric material or oxide gate dielectric, the access transistor, and a source terminal and a drain terminal on opposite sides of the memristive material according to an embodiment of the present invention;

FIG. 8 is a diagram illustrating an exemplary memristive device having a gate terminal and an (oxide) gate dielectric shared with an associated selector cell according to an embodiment of the present invention;

FIG. 9 is a diagram illustrating an exemplary memristive device having a gate terminal and a ferroelectric material shared with an associated selector cell according to an embodiment of the present invention;

FIG. 10 is a diagram illustrating an exemplary memristive device and associated selector cell that are separately gated according to an embodiment of the present invention;

FIG. 11 is a diagram illustrating an exemplary unit cell having two of the present memristive devices where the gate terminals of the memristive devices and the gate nodes of the access transistors are separately controlled through distinct word lines according to an embodiment of the present invention;

FIG. 12 is a diagram illustrating an exemplary unit cell also having two of the present memristive devices but where the gate terminals of the memristive devices and the gate nodes of the access transistors are controlled by the same signal driver according to an embodiment of the present invention;

FIG. 13 is a diagram illustrating an exemplary crossbar array of the present memristive devices with access transistors according to an embodiment of the present invention;

FIG. 14 is a diagram illustrating an exemplary crossbar array of the present memristive devices with selector cells according to an embodiment of the present invention; and

FIG. 15 is a diagram illustrating an exemplary methodology for operating the present memristive devices according to an embodiment of the present invention.

### DETAILED DESCRIPTION OF PREFERRED EMBODIMENTS

As described above, the threshold voltage in conventional memristive memory architectures is non-trivial, undesirably leading to increased power dissipation and area complexity tradeoffs. Advantageously, provided herein is a device-level approach to easily and effectively reduce the threshold voltage or V_{TH} of memristive memory devices and selector cells.

As will be described in detail below, the present devices uniquely employ a separate gate terminal offset from a memristive material by an insulator (e.g., an oxide or ferroelectric material) that, via field effects, reduces the V_{TH} of the devices. Namely, an external electric field applied to the gate terminal is used to build up charge in the memristive material, thereby modulating the Fermi level of the memristive material to alter the activation energy. The use of a ferroelectric insulator provides the added benefit of non-volatility. Namely, the gate terminal electric field will switch the ferroelectric material in a non-volatile way such that, even when voltage to the gate terminal is removed, that field will be maintained in the ferroelectric material.

Embodiments will be presented below where this unique gated design is implemented in memristive memory devices to lower their V_{TH}. These memristive memory devices can be included in circuit designs employing access transistors (in varying arrangements—see below) or, alternatively, in conjunction with (e.g., chalcogenide) selector cells. Like with the memristive memory devices, such selector cells too can benefit from a lowered V_{TH} if gated in the same manner.

The present threshold voltage tuning mechanism is attributable to an electrothermal model where the field and temperature dependent electrical conductivity of memristive materials such as chalcogenide phase change materials are coupled to a feedback mechanism. Namely, an increase in conductivity from an applied electric field induces a rise in lattice temperature. The increase in lattice temperature in turn increases the conductivity further. A key parameter governing these dynamics is the material dependent activation energy (Eₐ). Specifically, the exponential field dependence of conductivity a can be expressed as:

$$σ = e \cdot K \cdot {μ}_{0} \cdot exp ( \frac{- ( {E}_{a} - e F a )}{kT} ) ,$$

with self-heating T included as:

$$T = {T}_{a m b} + {R}_{t h} \cdot I \cdot V ,$$

where e is electronic charge, K is a constant, μ₀ is the band mobility, Eₐ is activation energy for conduction, F=V/uₐ is electric field on the memristive material with effective thickness uₐ whereby a is a (unphysical) fit parameter, T_{amb} is ambient temperature, and Rₜₕ is effective thermal resistance.

Electron instability from the applied electric field is the foundation for the electrothermal feedback mechanism. Under an applied input voltage, e.g., across source-drain terminals, the potential landscape of the memristive material is modified such that the Eₐ for charge transport is minimized. Beyond a certain input voltage value (called the V_{TH}) the lattice temperature increase induces a snap back where a significant amount of current flows through the memristive material. However, with conventional device designs, this V_{TH} value is high.

Advantageously, the present techniques offer another knob to regulate Eₐ using what is referred to herein as a gate energy parameter E_{G}. Here, E_{G} is realized using an additional terminal in the device, i.e., the gate terminal (GT), and an applied gate voltage or V_{G} which provides modulation of the Fermi level from gate induced changes in the carrier density in the memristive materials, and through that a decrease the Eₐ.

Doing so leverages the field effect in memristive materials. Specifically, applying V_{G} to the gate terminal causes charge to build up in the memristive material. The carrier density in the subthreshold regime of the memristive material can be determined as:

$$n ( F ) = \frac{2 K {k}_{B} T}{e F s} exp ( \frac{- {E}_{a}}{{k}_{B} T} ) sinh ( \frac{e F s}{2 {k}_{B} T} ) .$$

This charge build up changes the Fermi level of the memristive material, and thereby reducing the V_{TH}. For instance, Eₐ can be expressed as a function of a conductance band edge (E_{c}) and fermi level (E_{F}) of the memristive material and gate voltage (V_{G}), i.e.,

$${E}_{a} = {E}_{c} - {E}_{F} ( {V}_{G} ) .$$

Thus, with a gate voltage V_{G} applied, E_{F} can be altered. As a result, Eₐ will be decreased. Consequently, the self-heating in the device increases from the increased flow of current, which results in a decrease in the V_{TH}.

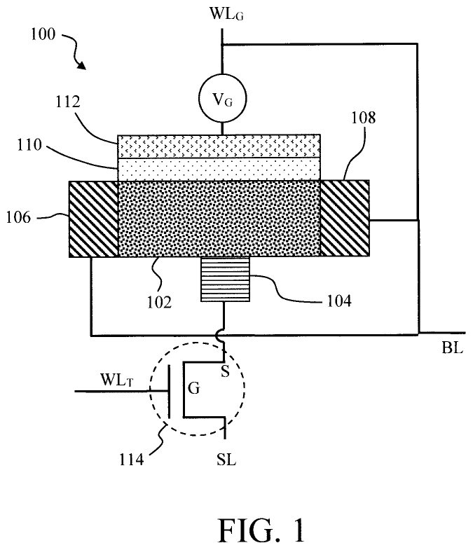

Given the above overview, an exemplary configuration of a memristive device 100 in accordance with the present techniques is shown illustrated in FIG. 1. As shown in FIG. 1, memristive device 100 includes a memristive material 102, a first electrode 104 directly contacting a bottom of the memristive material 102, a second electrode 106 and a third electrode 108 directly contacting opposite sides of the memristive material 102, a gate dielectric 110 directly contacting a top of the memristive material 102, and a gate terminal (GT) 112 directly contacting the gate dielectric 110 such that the gate dielectric 110 separates the gate terminal 112 from the memristive material 102. The first electrode 104 may also be referred to herein as a bottom electrode (BE), and the second electrode 106 and third electrode 108 may also be referred to herein as top electrodes (TEs).

Notably, due to the presence of the electrically insulating gate dielectric 110 between the gate terminal 112 and the memristive material 102, during operation no current will pass from the gate terminal 112 to the memristive material 102. Thus, a first voltage V_{G} applied to gate terminal 112 and the top electrodes, i.e., second electrode 106 and third electrode 108, will result in no current passing through the memristive material 102. It is this first voltage V_{G} that will be used to decrease the V_{TH} of the memristive material 102 via the above-described field effects. By contrast, applying a second voltage to first (bottom) electrode 104 will cause current to pass through the memristive material 102 between the first (bottom) electrode 104 and the top electrodes, i.e., second electrode 106 and third electrode 108, since there is no insulator present between either the top or bottom electrodes and the memristive material 102.

For instance, referring to the example depicted in FIG. 1, a first word line is connected to gate terminal 112 (and thus the first word line is also referred to herein as a gate word line or WL_{G}), a bit line (BL) is connected to the top electrodes, i.e., second electrode 106 and third electrode 108, a source line (SL) connects a source node (S) of an access transistor 114 to the first (bottom) electrode 104, and a second word line is connected to a gate node (G) of the access transistor 114 (and thus the second word line is also referred to herein as a transistor word line or WL_{T}). As will be described in detail below, during operation a first voltage V_{G} is applied, via the WL_{G} and BL, to the gate terminal 112 and top electrodes, i.e., second electrode 106 and third electrode 108, respectively. It is this first voltage V_{G} that is used lower the V_{T} based on field effects in the memristive material 102. For instance, depending on the given memristive material and device geometry, threshold voltages for the present memristive materials in a full amorphous state (without V_{G}) can be in the range of from about 1.5 volts (V) to about 5.0 V. By contrast, with the application of V_{G}, a reduction in V_{T} of greater than two times (2×) these values can be achieved due to the non-linear dependence of material conductivity on the activation energy Eₐ. A second voltage supplied through access transistor 114 is applied to the first (bottom) electrode 104, second electrode 106 and third electrode 108. It is this second voltage that is used to program the resistance of the memristive material 102. As highlighted above, access transistor 114 is controlled via the WL_{T}.

The term ‘memristive material’ refers to any material whose resistance can be programmed in order to store information, such as by switching the memristive material or a portion thereof from a high resistance state to a low resistance state, and vice versa. Notably, the present techniques generally apply to the use of any memristive materials where the switching mechanism thereof can have a thermal dependence, such that the increased conductivity via a gate field allows for improved power dissipation (i.e., heating) which, in turn, accelerates the switching (see above). Thus, a wide variety of materials can be employed as memristive material 102 in accordance with the present techniques. For instance, according to an exemplary embodiment, memristive material 102 is a phase change material. In the sense that it can exist in amorphous and crystalline form almost any material is a phase change material, such as metals, semiconductors or insulators. However, only a small group of materials has the properties that makes them technologically useful phase change materials, with high on/off resistance ratio, fast switching times and good data retention. Many technologically relevant phase change materials are chalcogenides, i.e., they contain one or more chalcogenide elements. These are Group 16 in the periodic table, e.g., sulfur (S), selenium (Se) and/or tellurium (Te). According to one exemplary embodiment, the phase change material is a chalcogenide alloy that includes the chalcogenide element Te, in addition to other elements such as antimony (Sb) and/or germanium (Ge), forming the alloys Sb₂Te₃, GeTe, and Ge₂Sb₂Te₅ (GST 225). Other technologically relevant phase change materials that are not chalcogenides include III-V semiconductor materials (such as gallium antimonide (GaSb)) or Ge—Sb based alloys. Often additional elements such as silver (Ag), indium (In), nitrogen (N) or bismuth (Bi) are added to the phase change alloys to optimize their properties.

A phase change material can be switched between two states, poly-crystalline (or single-crystal) and amorphous. In the poly-crystalline state, each grain of the phase change material is a perfect crystal and the phase change material is conductive (almost metallic). It is notable however that each of the grains is randomly oriented with respect to the other grains resulting in an overall poly-crystalline material. In the amorphous state, there is no order in the material and the phase change material is highly resistive. These two states make phase change materials particularly well-suited for storing data.

According to another exemplary embodiment, memristive material 102 is an organic semiconductor and/or a two-dimensional (2D) semiconductor material. Suitable organic semiconductors include, but are not limited to, organic polymers such as Tris-(8-hydroxyquinoline)aluminum, poly(3-hexylthiophene-2,5-diyl) (or P3HT), polyaniline (or PANI), poly[2-methoxy-5-(2-ethylhexyloxy)-1,4-phenylenevinylene], phthalocyanine, polyphenylene vinylene (or PPV), polyvinylphenol (or PVP), polyvinyl alcohols. pentacene, polypyrrole and/or polycarbazole and/or organic-inorganic hybrid materials such as organic-inorganic perovskite materials. Suitable 2D semiconductor materials include, but are not limited to, nanowires and/or graphene. Notably, the switching mechanism in such materials can have a thermal dependence, just like phase change materials. As such, these organic and 2D semiconductor materials can also benefit from the increased conductivity and improved power dissipation (i.e., heating) from a gate field which, in turn, accelerates their switching.

The first electrode 104, second electrode 106 and third electrode 108 can each be formed from a material or a combination of materials. For instance, suitable materials for the first electrode 104, second electrode 106 and third electrode 108 include, but are not limited to, metals such as copper (Cu), nickel (Ni), platinum (Pt), titanium (Ti), tungsten (W), cobalt (Co), ruthenium (Ru), aluminum (Al), tantalum (Ta), titanium nitride (TiN), tantalum nitride (TaN), aluminum-containing alloys such as titanium aluminide (TiAl), titanium aluminum nitride (TiAlN), titanium aluminum carbide (TiAlC), tantalum aluminide (TaAl), tantalum aluminum nitride (TaAlN), tantalum aluminum carbide (TaAlC), titanium-containing alloys such as titanium carbide (TiC), tantalum titanium (TaTi), and any combinations thereof.

The gate dielectric 110 is an electrical insulator meaning, as highlighted above, that it will prevent current flow between the gate terminal 112 and the top electrodes, i.e., second electrode 106 and third electrode 108. According to an exemplary embodiment, the gate dielectric 110 is an oxide dielectric material. Suitable oxide dielectric materials include, but are not limited to, silicon oxide (SiOx) and/or high-κ dielectric materials such as hafnium oxide (HfO₂), lanthanum oxide (La₂O₃), hafnium-lanthanum oxide (HfLaO₂), hafnium zirconium oxide (HfZrO₂), hafnium aluminum oxide (HfAlO₂), titanium oxide (TiO₂) and/or zirconium oxide (ZrO₂). The term “high-κ,” as used herein, refers to a material having a relative dielectric constant x which is much higher than that of silicon dioxide (e.g., a dielectric constant κ=25 for HfO₂ rather than 4 for SiO₂). In one exemplary embodiment, gate dielectric 110 has a thickness of from about 1 nanometer (nm) to about 5 nm.

The gate terminal 112 can be configured similar to the first electrode 104, second electrode 106 and third electrode 108. For instance, according to an exemplary embodiment, the gate terminal 112 is formed from a metal(s) such as Cu, Ni, Pt, Ti, W, Co, Ru, Al, Ta, TiN, TaN, aluminum-containing alloys such as TiAl, TiAlN, TiAlC, TaAl, TaAlN, TaAlC, titanium-containing alloys such as TiC, TaTi, and any combinations thereof.

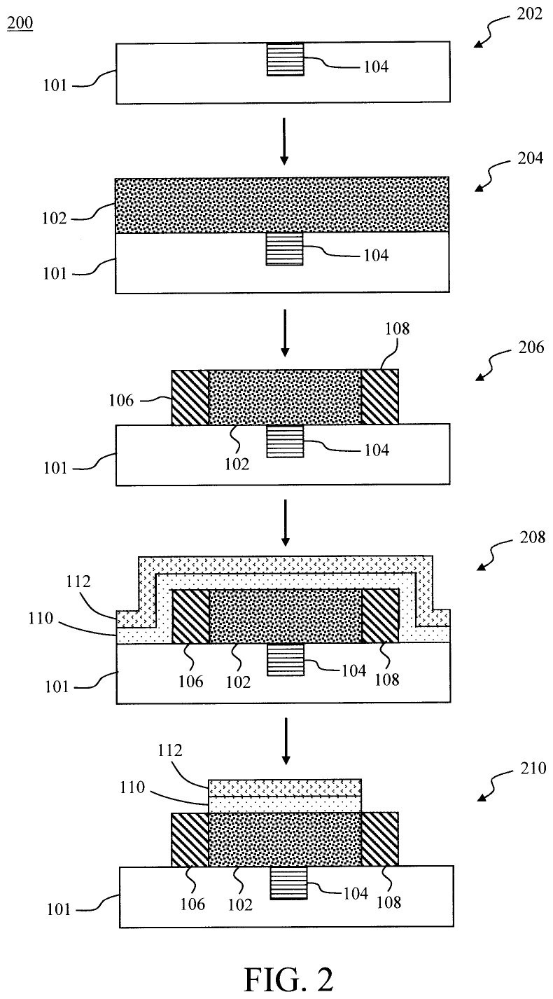

An exemplary methodology 200 for fabricating memristive device 100 is now described by way of reference to FIG. 2. In step 202, first (bottom) electrode 104 is formed in a substrate 101. It is notable that, for ease and clarity of depiction, substrate 101 is not shown in FIG. 1. According to an exemplary embodiment, substrate 101 is a bulk semiconductor wafer, such as a bulk silicon (Si), bulk germanium (Ge), bulk silicon germanium (SiGe) and/or bulk III-V semiconductor wafer. Alternatively, substrate 101 can be a semiconductor-on-insulator (SOI) wafer. A SOI wafer includes a SOI layer separated from an underlying substrate by a buried insulator. When the buried insulator is an oxide it is also referred to herein as a buried oxide or BOX. The SOI layer can include any suitable semiconductor material(s), such as Si, Ge, SiGe and/or a III-V semiconductor. Further, substrate 101 may already have pre-built structures (not shown) such as transistors, diodes, capacitors, resistors, interconnects, wiring, etc. For instance, access transistor 114 and the associated SL and WL_{T} wiring (see above) may be pre-built into substrate 101.

A metallization process such as a damascene approach or other suitable technique is then used to form the first (bottom) electrode 104 in substrate 101. As provided above, suitable materials for the first (bottom) electrode 104 include, but are not limited to, metal(s) such as Cu, Ni, Pt, Ti, W, Co, Ru, Al, Ta, TiN, TaN, aluminum-containing alloys such as TiAl, TiAlN, TiAlC, TaAl, TaAlN, TaAlC, titanium-containing alloys such as TiC, TaTi, and any combinations thereof, which can be deposited using a process or combination of processes including, but not limited to, chemical vapor deposition (CVD), atomic layer deposition (ALD), physical vapor deposition (PVD), sputtering, plating, evaporation, ion beam deposition, electron beam deposition, laser assisted deposition, chemical solution deposition, etc. According to an exemplary embodiment, the metal overburden is removed, e.g., using an etching process like chemical-mechanical planarization (CMP), such that a topmost surface of the first (bottom) electrode 104 is coplanar with a topmost surface of the substrate 101, as shown in FIG. 2.

In step 204, the memristive material 102 is deposited onto the substrate 101 over the first (bottom) electrode 104 such that the memristive material 102 directly contacts the first (bottom) electrode 104. As provided above, suitable memristive materials 102 include, but are not limited to, phase change materials such as chalcogenide alloys that include Te, in addition to other elements such as Sb and/or Ge, forming alloys such as Sb₂Te₃, GeTe, and Ge₂Sb₂Te₅ (GST 225) and/or non-chalcogenides such as III-V semiconductor materials, e.g., GaSb, or Ge—Sb based alloys, any of which can optionally contain additional elements such as Ag, In, N or Bi, organic semiconductors such as organic polymers like Tris-(8-hydroxyquinoline)aluminum, poly(3-hexylthiophene-2,5-diyl) (or P3HT). polyaniline (or PAN I), poly[2-methoxy-5-(2-ethylhexyloxy)-1,4-phenylenevinylene], phthalocyanine, polyphenylene vinylene (or PPV), polyvinylphenol (or PVP), polyvinyl alcohols, pentacene, polypyrrole and/or polycarbazole and/or organic-inorganic hybrid materials such as organic-inorganic perovskite materials and/or 2D semiconductor materials such as nanowires and/or graphene. According to an exemplary embodiment, the memristive material 102 is a phase change material deposited using a process such as PVD or CVD. The specific targets (PVD) or precursors (CVD) for the deposition process depend of course on the particular phase change material being formed. For example, when physical vapor deposition (PVD) is used to deposit Ge₂Sb₂Te₅ the most common source is a Ge₂Sb₂Te₅ target. Separate elemental Ge, Sb and Te targets can also be used by adjusting the flux from each target to obtain the desired composition. In another example, molecular beam epitaxy (MBE) can also be used to deposit Ge₂Sb₂Te₅. When MBE is used the sources are usually individual Knudsen effusion cells. Each cell contains one of the alloy elements (Ge, Sb or Te), and the flux of each element is controlled by the effusion cell temperature. According to an exemplary embodiment, the deposition of the phase change material is performed at a high substrate temperature, for example, at a substrate temperature of from about 150 degrees Celsius (° C.) to about 300° C. For example, for Ge₂Sb₂Te₅ the preferred temperature range is from about 175° C. to about 200° C. The result is formation of a crystalline phase change material. A room temperature deposition would typically yield amorphous material when Ge₂Sb₂Te₅ is deposited. However, some phase change materials such as Sb₂Te₃ would be crystalline even at deposition temperatures below 100° C. Alternatively, when the memristive material 102 is an organic or 2D semiconductor, a process such as molecular layer deposition (MLD) or atomic layer deposition (ALD) can be employed to deposit the organic semiconductor as the memristive material 102 onto the substrate 101, while a casting process such as spin-coating or spraying can be used to deposit 2D semiconductors as the memristive material 102 onto the substrate 101.

In step 206, the memristive material 102 is patterned, and the top electrodes, i.e., second electrode 106 and third electrode 108, are formed on substrate 101 directly contacting opposite sides of the memristive material 102. Standard lithography and etching techniques can be employed to pattern the memristive material 102. As provided above, suitable materials for the second electrode 106 and third electrode 108 include, but are not limited to, metal(s) such as Cu, Ni, Pt, Ti, W, Co, Ru, Al, Ta, TiN, TaN, aluminum-containing alloys such as TiAl, TiAlN, TiAlC, TaAl, TaAlN, TaAlC, titanium-containing alloys such as TiC, TaTi, and any combinations thereof, which can be deposited using a process or combination of processes including, but not limited to, CVD, atomic layer ALD, PVD, sputtering, plating, evaporation, ion beam deposition, electron beam deposition, laser assisted deposition, chemical solution deposition, etc. The metal overburden can then be removed using a process such as CMP.

In step 208, the gate dielectric 110 is deposited onto the substrate 101, memristive material 102, and second electrode 106 and third electrode 108, and the gate terminal 112 is formed on the gate dielectric 110. As provided above, suitable materials for the gate dielectric 110 include, but are not limited to, oxide dielectric materials such as SiOx, HfO₂, La₂O₃, HfLaO₂, HfZrO₂, HfAlO₂, TiO₂ and/or ZrO₂, which can be deposited using a process such as CVD, ALD or PVD. Embodiments will be presented below where a ferroelectric insulator is employed, rather than an oxide material. In that case, deposition processes such as thermal evaporation or sputtering may be preferred. As provided above, suitable materials for the gate terminal 112 include, but are not limited to, metal(s) such as Cu, Ni, Pt, Ti, W, Co, Ru, Al, Ta, TiN, TaN, aluminum-containing alloys such as TiAl, TiAlN, TiAlC, TaAl, TaAlN, TaAlC, titanium-containing alloys such as TiC, TaTi, and any combinations thereof, which can be deposited using a process or combination of processes including, but not limited to, CVD, atomic layer ALD, PVD, sputtering, plating, evaporation, ion beam deposition, electron beam deposition, laser assisted deposition, chemical solution deposition, etc.

In step 210, standard lithography and etching techniques are used to pattern the gate dielectric 110 and gate terminal 112. Following patterning, the gate dielectric 110 and gate terminal 112 are present over only the memristive material 102, and thus no longer cover the substrate 101 nor the second electrode 106 or third electrode 108, as shown in FIG. 2.

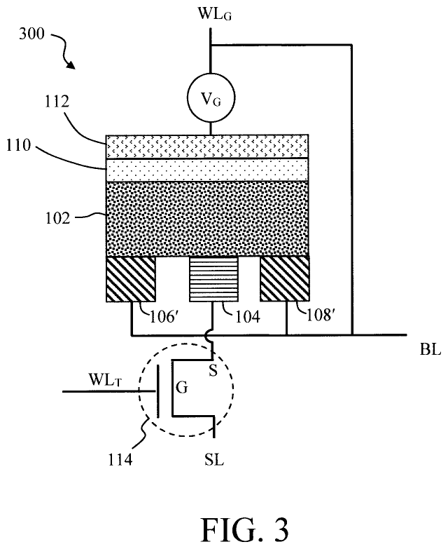

Several different derivations of the present design are contemplated herein. For instance, referring to FIG. 3, a memristive device 300 configuration is shown where the top electrodes are relocated to the bottom of the memristive material. Many of the structures in this design are the same as that depicted in FIG. 1, and described above. In that regard, like structures are numbered alike in the figures.

Namely, as shown in FIG. 3, with this configuration the first electrode 104 and the second and third electrodes (here given the reference numerals 106′ and 108′, respectively) all directly contact the bottom of the memristive material 102, with the first electrode 104 being situated in between the second electrode 106′ and the third electrode 108′. Thus, in the same manner as descried above, current can pass through the memristive material 102 between the first electrode 104 and the second electrode 106′/third electrode 108′, since there is no insulator present between any of these electrodes and the memristive material 102. By contrast, due to the presence of the electrically insulating gate dielectric 110 between the gate terminal 112 and the memristive material 102, no current will pass from the gate terminal 112 to the second electrode 106′ or third electrode 108′. In this manner, an applied gate voltage V_{G} can thus be used to alter (i.e., decrease) the V_{TH} of the memristive material 102 via the above-described field effects. Suitable materials for the second electrode 106 and third electrode 108 were described in accordance with the description of FIG. 1, above. Those same materials may be employed for second electrode 106′ and third electrode 108′.

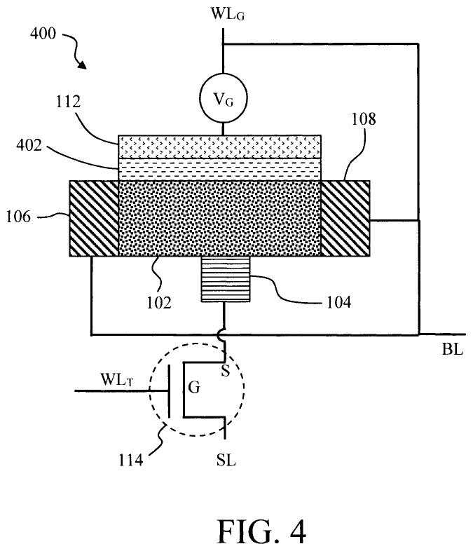

As highlighted above, the present gated designs can also leverage the non-volatility of a ferroelectric material. Like the above gate dielectric, ferroelectric materials are electrical insulators, and thus too can serve as a barrier to current flow. For instance, referring to FIG. 4, a memristive device 400 configuration is shown where the gate terminal 112 is separated from the memristive material 102 by a ferroelectric material. Many of the structures in this design are the same as that depicted in FIG. 1, and described above. In that regard, like structures are numbered alike in the figures.

As shown in FIG. 4, with this configuration it is a ferroelectric material 402 that separates (and electrically isolates) the gate terminal 112 from the memristive material 102. In general, ferroelectrics are a class of materials that exhibit spontaneous polarization below a certain temperature forming ferroelectric domains in the material, i.e., an area(s) of oriented spontaneous polarization. It is at this temperature that the subject material undergoes a phase transition from a low-temperature ferroelectric phase to a high-temperature paraelectric phase upon heating.

Advantageously, the direction of the polarization of these ferroelectric domains can be modified by an applied electric field.

Suitable ferroelectric materials include, but are not limited to, potassium sodium tartrate (KNaC₄H₄O₆·4H₂O), bismuth titanate (Bi₄Ti₃O₂), barium titanate (BaTiO₃), barium strontium titanate (Ba_{0.73}Sr_{0.27}TiO₃), lead zirconate titanate (PbZr₁₋ₓTiₓO₃), lead titanate (PbTiO₃), lead zirconate (PbZrO₃), lithium niobate (LiNbO₃), potassium niobate (KNbO₃), lead bismuth niobate (PbBi₂Nb₂O₉), potassium dihydrogen phosphate (KH₂PO₄), guanidine aluminum sulfate hexahydrate (C(NH₂)₃Al(SO₄)₂·6H₂O), strontium bismuth tantalate (SrBi₂Ta₂O₉), and any combinations thereof. In one exemplary embodiment, the ferroelectric material 402 has a thickness of from about 1 nanometer (nm) to about 5 nm.

Thus, in the same manner as described above, during operation a first voltage V_{G} (applied via the (first word line WL_{G} and BL to the gate terminal 112 and top electrodes, i.e., second electrode 106 and third electrode 108, respectively) is used to lower the V_{T} based on field effects in the memristive material 102, while a second voltage (applied via the SL to the first (bottom) electrode 104) through access transistor 114, which is controlled via the second word line WL_{T}, is used to program the resistance of the memristive material 102. Additionally, in this example, by enabling the WL_{G}, a perpendicular gate field can be applied to the memristive material 102 in a non-volatile manner by switching the polarization of the ferroelectric domains. As such, the field does not collapse when WL_{G} is turned off (as is the case when a non-ferroelectric oxide dielectric material as in the previous embodiment is employed) thereby storing the gate voltage V_{G} history, i.e., the polarity of the last applied V_{G} which changes the direction of the polarization state of the ferroelectric domains and thus is stored in the ferroelectric material 402.

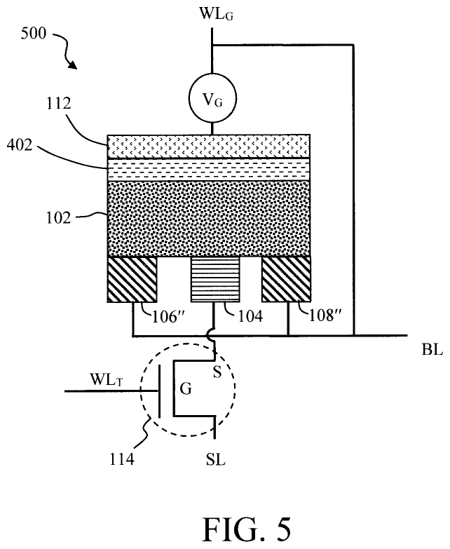

Referring to memristive device 500 of FIG. 5, a derivation of this design is shown where the gate terminal 112 is separated from the memristive material 102 by the ferroelectric material 402, and the top electrodes are also relocated to the bottom of the memristive material. Many of the structures in this design are the same as that depicted in FIG. 2, and described above. In that regard, like structures are numbered alike in the figures.

Namely, as shown in FIG. 5, with this configuration the first electrode 104 and the second and third electrodes (here given the reference numerals 106″ and 108″, respectively) all directly contact the bottom of the memristive material 102, with the first electrode 104 being situated in between the second electrode 106″ and the third electrode 108″. Thus, in the same manner as descried above, current can pass through the memristive material 102 between the first electrode 104 and the second electrode 106″/third electrode 108″, since there is no insulator present between any of these electrodes and the memristive material 102. By contrast, due to the presence of the electrically insulating ferroelectric material 402 between the gate terminal 112 and the memristive material 102, no current will pass from the gate terminal 112 to the second electrode 106″ or third electrode 108″. In this manner, an applied gate voltage V_{G} can thus be used to alter (i.e., decrease) the V_{TH} of the memristive material 102 via the above-described field effects. Suitable materials for the second electrode 106 and third electrode 108 were described in accordance with the description of FIG. 1, above. Those same materials may be employed for second electrode 106″ and third electrode 108″.

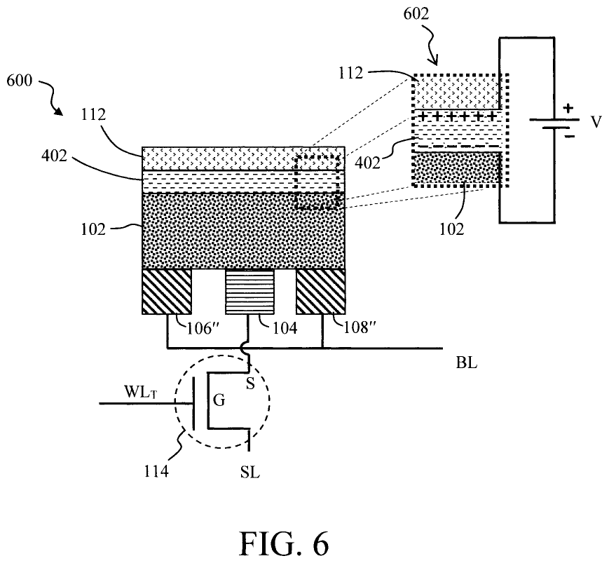

Further in regard to the use of ferroelectric materials in the present memristive device design, embodiments are also contemplated herein where the polarization of the ferroelectric domains within the ferroelectric material 402 are pre-aligned during manufacturing. In that case, the first word line WL_{G} can be removed from memristive device 500. See, for example, memristive device 600 shown in FIG. 6. Many of the structures in this design are the same as that depicted in FIG. 5, and described above. In that regard, like structures are numbered alike in the figures. By ‘pre-aligned’ it is meant that the ferroelectric domains within the ferroelectric material 402 do not need to be switched during operation, hence eliminating the need for a word line WL_{G} altogether. For instance, during manufacturing, a voltage V applied across the ferroelectric material 402 during manufacture of memristive device 600 can be used to pre-align the ferroelectric domains such that there is a net positive (+) charge on one side of the ferroelectric material 402 and a net negative charge on the other side of ferroelectric material 402. See magnified view 602. Advantageously, as described in detail above, even when the voltage V is removed, the ferroelectric material 402 will retain this field during subsequent use of memristive device 600.

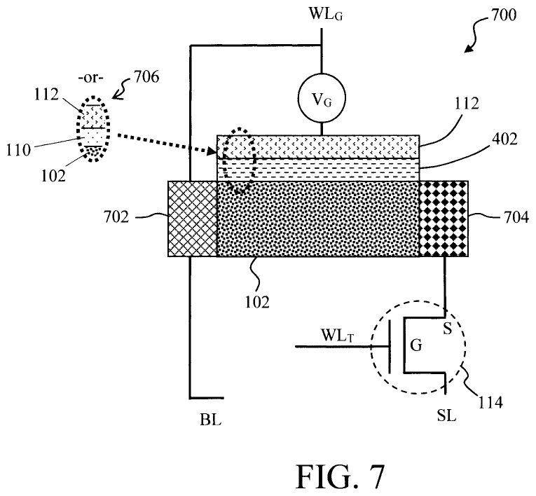

Each of the designs described thus far has been a four-terminal device, i.e., having a first electrode, a second electrode and a third electrode, and a gate terminal. However, other configurations are also contemplated herein. For instance, by way of example only, by connecting the BL to an electrode on only one side of the memristive material 102 (referred to herein as a source electrode 702), and connecting the access transistor 114 to an electrode on only an opposite side of the memristive material 102 (referred to herein as a drain electrode 704), then the need for a bottom electrode is eliminated, resulting in a three-terminal device. See, for example, memristive device 700 shown in FIG. 7. As shown in FIG. 7, the source electrode 702 and the drain electrode 704 each directly contact the memristive material 102.

The terms ‘source’ and ‘drain’ are used to distinguish the terminal for the BL from the terminal for the access transistor 114, and vice versa, as opposed to the symmetric (second/third) top electrodes in the previous designs. However, the source electrode 702 and the drain electrode 704 can be configured similar to the top electrodes. For instance, according to an exemplary embodiment, the source electrode 702 and the drain electrode 704 are each formed from a material or a combination of materials including metals such as Cu, Ni, Pt, Ti, W, Co, Ru, Al, Ta, TiN, TaN, aluminum-containing alloys such as TiAl, TiAlN, TiAlC, TaAl, TaAlN, TaAlC, titanium-containing alloys such as TiC, TaTi, and any combinations thereof.

Further, while memristive device 700 shown in FIG. 7 has ferroelectric material 402 as the electrical insulator separating the gate terminal 112 from the memristive material 102, this is only an example, and it is to be understood that the electrical insulator in between the gate terminal 112 and the memristive material 102 can instead be an oxide material. Thus, embodiments are contemplated herein where memristive device 700 employs gate dielectric 110 instead of ferroelectric material 402. See, e.g., inset 706.

In the preceding examples, an access transistor 114 is used as the memristive selector. However, embodiments are also contemplated herein where (e.g., chalcogenide) selector cells are instead used in this capacity. Advantageously, in the present selector-based designs the above-described field effect can also be leveraged to modulate the threshold voltages of the selector cells. As will be described in detail below, this can be done by modulating both the memristive device and the associated selector cell through a shared electrical connection, or through distinct connections.

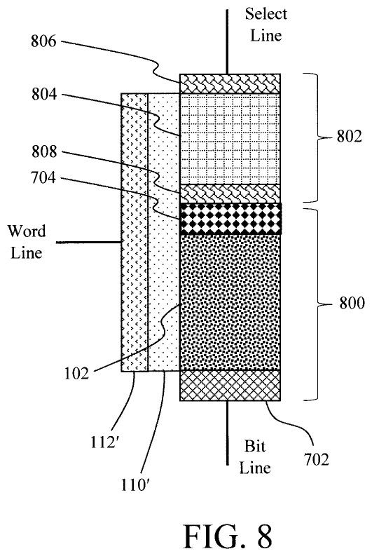

For instance, in one exemplary embodiment, a gate dielectric and gate terminal are shared across a memristive device 800 and adjacent selector cell 802. See FIG. 8. As shown in FIG. 8, memristive device 800 is configured similar to the three-terminal design described in conjunction with the description of memristive device 700 of FIG. 7, above. Namely, memristive device 800 has the source electrode 702 and the drain electrode 704 each directly contacting opposite sides of the memristive material 102. Here, however, the gate dielectric and gate terminal which for ease and clarity of depiction are given the reference numerals 110′ and 112′, respectively, extend across both the memristive device 800 and the selector cell 802. As such, the gate terminal 112′ is a shared electrical connection between these components. Suitable materials for the gate dielectric 110 and gate terminal 112 were described in accordance with the description of FIG. 1, above. Those same materials may be employed for gate dielectric 110′ and gate terminal 112′.

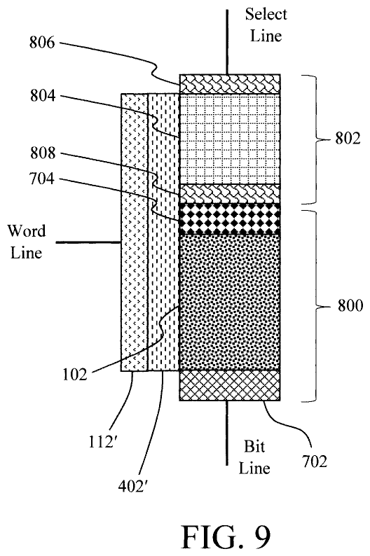

It is notable that, while the electrical insulator in between the gate terminal 112′ and the memristive material 102 is in this example an oxide material, embodiments are contemplated herein where a ferroelectric material is employed instead of the gate dielectric 110′. See, e.g., FIG. 9—described below.

The selector cell 802 includes a selector material 804, the (shared) gate terminal 112′ separated from the selector material 804 by the (shared) electrically insulating gate dielectric 110′, and a selector source electrode 806 and a selector drain electrode 808 each directly contacting opposite sides of the selector material 804. Like the access transistor 114 in the previous examples, the role of selector cell 802 is to enable access to particular memristive devices in an array (see below), and suppress unwanted current flow in unselected devices. An added advantage is that selector cell 802 can also benefit from the present gated designs to build up charge in the selector material 804, thereby modulating the Fermi level in the selector material 804 and reducing the threshold voltage of the selector cell 802. In this particular embodiment, this threshold voltage adjustment is achieved via the gate terminal 112′ and the gate dielectric 110′ which are both shared across the memristive material 102 and the selector material 804. Namely, as shown in FIG. 8, the gate terminal 112′ and the gate dielectric 110′ span both the memristive material 102 and the selector material 804, crossing over the drain electrode 704 and selector drain electrode 808 therebetween. Notably, the gate dielectric 110′ fully separates and electrically insulates the gate terminal 112′ from the memristive material 102 and selector material 804.

During operation, selector cell 802 undergoes a transition between a low conducting state and a high conducting state through a region of negative differential resistance, exhibiting a non-linear conduction. A threshold current is needed to keep the selector cell 802 in a high conducting state. According to an exemplary embodiment, selector material 804 is a chalcogenide material such as germanium selenium (GeSe), silicon tellurium (SiTe), silicon selenide (SiSe), and combinations thereof.

As shown in FIG. 8, a single word line or WL is connected to the (shared) gate terminal 112′ across the memristive material 102 and the selector material 804, and can be used to lower the threshold voltage of the memristive device 800 and selector cell 802 via the above-described field effects. A select line is connected to the selector source electrode 806. A bit line or BL is connected to the source electrode 702 (of memristive device 800). Notably, the drain electrode 704 (of memristive device 800) and the selector drain electrode 808 (of selector cell 802) directly contact one another. Thus, by this configuration, selection and programming of memristive device 800 can be achieved via the select line and bit line.

As highlighted above, this shared gate configuration can also be implemented with a shared ferroelectric material (which for ease and clarity of depiction is given the reference numeral 402′) rather than an oxide material to remember the applied gate field history. See, for example, FIG. 9. Suitable ferroelectric materials 402 were described in accordance with the description of FIG. 4, above. Those same materials may be employed for ferroelectric material 402′.

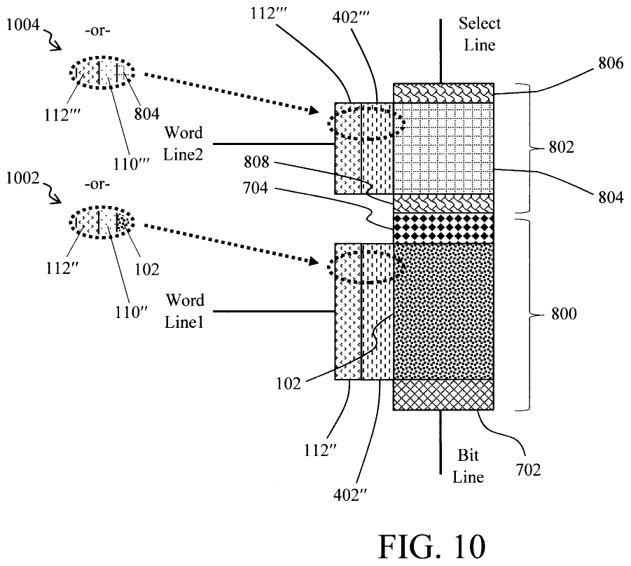

Alternatively, the memristive device 800 and selector cell 802 can be separately gated. See, for example, FIG. 10. As shown in FIG. 10, a separate ferroelectric material and gate terminal (which for ease and clarity of depiction are given the reference numerals 402″ and 112″, respectively) is provided for the memristive device 800, while another ferroelectric material 402′″ and gate terminal 112′″ are provided for the selector cell 802. Accordingly, with this design, separate word lines, i.e., Word Line1 and Word Line2, are connected to gate terminal 112″ and gate terminal 112′″, respectively. Doing so enables the selective modulation of the memristive device 800 threshold voltage irrespective of the selector cell 802, and vice versa. Suitable ferroelectric materials 402 and gate terminal 112 materials were described for example in accordance with the description of FIGS. 1 and 4, above. Those same materials may be employed for ferroelectric material 402″/402′″ and gate terminal 112″/112′″.

Further, while FIG. 10 depicts a ferroelectric material 402″/402′″ as the electrical insulator separating the gate terminal 112″/112′″ from the memristive material 102 and selector material 804, respectively, this is only an example, and it is to be understood that the electrical insulator in between the gate terminal 112″/112′″ and the memristive material 102/selector material 804 can instead be an oxide material. Thus, embodiments are contemplated herein where (an oxide) gate dielectric 110″/110′″ is employed instead of ferroelectric material 402″/402′″. See, e.g., insets 1002 and 1004. Suitable oxide gate dielectric materials were provided above.

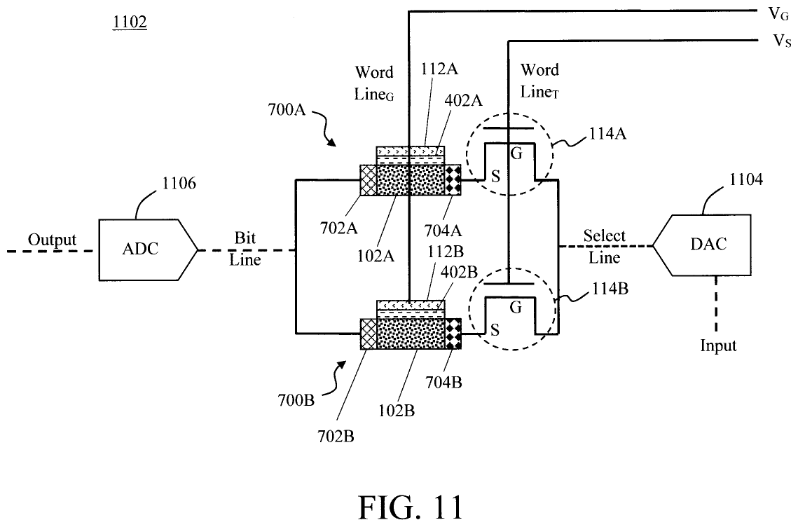

Systems including at least one of the present memristive devices are also contemplated herein. For instance, FIG. 11 is a diagram illustrating a unit cell 1102 having two of the present memristive devices. For illustrative purposes only, the device configurations used in this example are that of memristive device 700 described in conjunction with the description of FIG. 7, above. However, it is to be understood that the layout of unit cell 1102 can be applied to any of the memristive designs presented herein. The designations A and B are used to distinguish the components of one instance 700A of memristive device 700 from those of another instance of 700B of memristive device 700. Further, as shown and described in detail in accordance with the description of FIG. 7 above, while memristive devices 700A and 700B are shown having ferroelectric material 402A and 402B, respectively, as the electrical insulator, it is to be understood that the electrical insulator can instead be an oxide material such as gate dielectric 110.

As shown in FIG. 11, the gate terminals 112A and 112B of the memristive devices 700A and 700B, respectively, and the gate nodes of the access transistors 114A and 114B are separately controlled through distinct word line, i.e., Word Line Gate or Word Line_{G} controls the former via a gate voltage V_{G} and Word Line Transistor or Word Line_{T} controls the latter via a source voltage V_{S}. During programming, the gate Word Line_{G} is enabled for threshold voltage reduction. Input to the unit cell 1102 passes through a digital to analog converter or DAC 1104 which is connected to a source node of the access transistors 114A and 114B via a Select Line. Output from the memristive devices 700A and 700B passes through an analog to digital converter or ADC 1106 via a Bit Line.

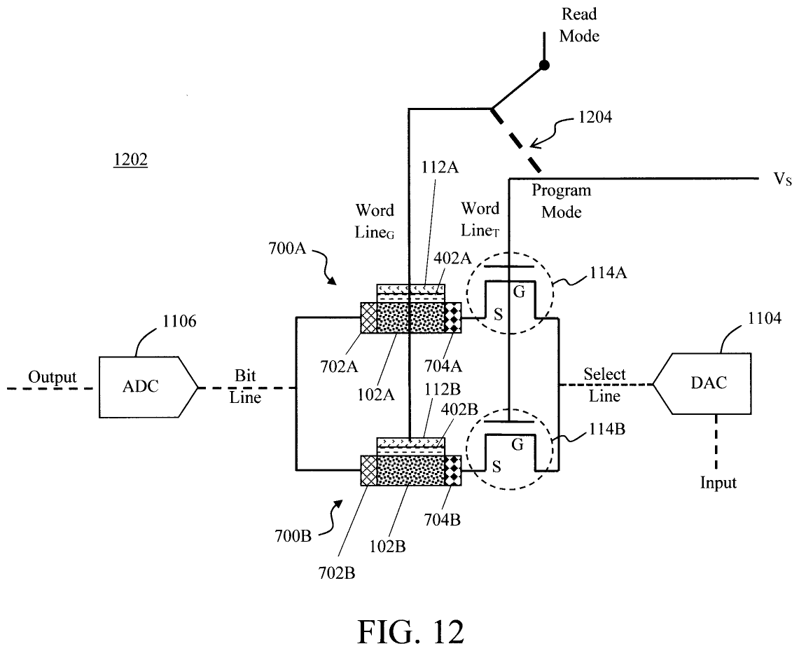

A derivation of this unit cell design is also contemplated herein where the gate terminals 112A and 112B of the memristive devices 700A and 700B, respectively, and the gate nodes of the access transistors 114A and 114B are controlled by the same signal driver. See, for example, unit cell 1202 in FIG. 12. Namely, as shown in FIG. 12, during programming the gate Word Line_{G} is enabled by connecting it to the source voltage V_{S} via the transistor Word Line_{T}. See connection 1204. During read operation, the connection 1204 is removed such that the Bit Line and gate Word Line_{G} are at the same voltage and no field exists.

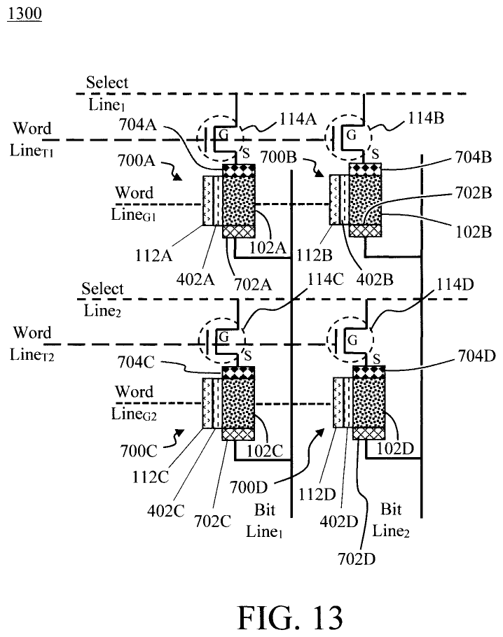

As highlighted above, crossbar layouts of the present memristive device unit cells may be implemented. See, for example, crossbar array 1300 shown in FIG. 13. For illustrative purposes only, the device configurations used in this example are that of memristive device 700 described in conjunction with the description of FIG. 7, above. However, it is to be understood that the layout of crossbar array 1300 can be applied to any of the access transistor-based memristive designs presented herein. Further, the designations A, B, C and D are used to distinguish the components of one instance 700A/C of memristive device 700 from those of another instance of 700B/C of memristive device 700 in each of the unit cells of the array. Further, as shown and described in detail in accordance with the description of FIG. 7 above, while memristive devices 700A,B,C and D are shown having ferroelectric material 402A,B,C and D as the electrical insulator, it is to be understood that the electrical insulator can instead be an oxide material such as gate dielectric 110. As shown in FIG. 13, access to the memristive devices 700A,B,C and D is provided through access transistors 114A,B,C and D. In this design, the transistor word lines, i.e., Word Line_{T1}, Word Line_{T2}, etc. are separate from the gate word lines, i.e., Word Line_{G1}, Word Line_{G2}, etc.

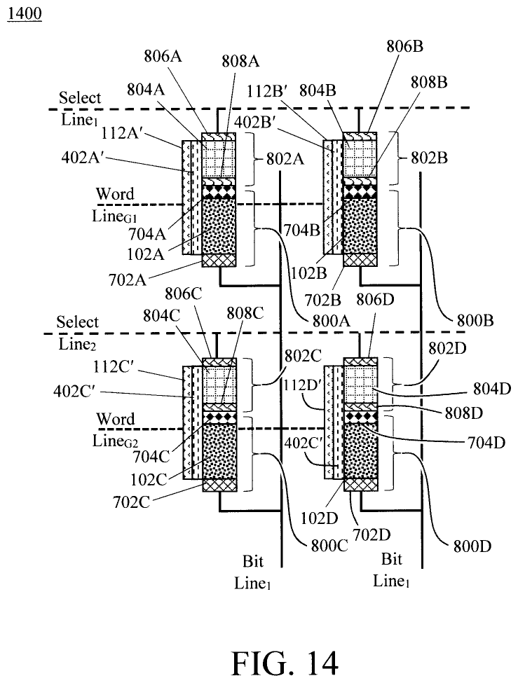

A similar crossbar layout can also be implemented using the present memristive devices having selector cells. See, for example, crossbar array 1400 shown in FIG. 14. For illustrative purposes only, the device configurations used in this example are that of the shared gate terminal design described in conjunction with the description of FIG. 9, above. However, it is to be understood that the layout of crossbar array 1400 can be applied to any of the selector cell-based memristive designs presented herein. In the same convention as above, the designations A, B, C and D are used to distinguish the components of one instance of a paired memristive device 800/selector cell 802 from those of another. Further, as described in detail in accordance with the description of FIG. 8 above, while the shared electrical insulator is shown as a ferroelectric material 402′A,B,C and D, it is to be understood that the electrical insulator can instead be an oxide material such as gate dielectric 110′. As shown in FIG. 14, access to the memristive devices 800A,B,C and D is provided through selector cells 802A,B,C and D. In this design, the word lines of the memristive devices 800A,B,C and D and the selector cells 802A,B,C and D are shared, i.e., Word Line_{G1}, Word Line_{G2}, etc. based on the shared gate design where the gate terminal 112A′,B′,C′ and D′ spans both the memristive material 102A,B,C and D and selector material 804A,B,C and D in each memristive device/selector cell pair.

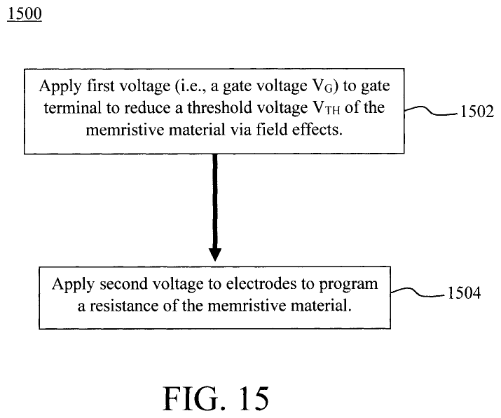

FIG. 15 is a diagram illustrating an exemplary methodology 1500 for operating a memristive device in accordance with the present techniques. For illustrative purposes only, the reference numerals associated with memristive device 100 of FIG. 1 may be used in the description. However, it is to be understood that methodology 1500 is generally applicable to any of the memristive device designs presented herein.

In step 1502, a first voltage (also referred to herein as a gate voltage or V_{G}) is applied to the gate terminal 112. As described in detail above, the gate terminal 112 is separated from the memristive material 102 by an electrical insulator, which prevents current flow through the memristive material 102 from the applied V_{G}. This electrical insulator can be a gate dielectric 110 such as an oxide material, or alternatively a ferroelectric material such as ferroelectric material 402 (see, e.g., FIG. 4). As highlighted above, the use of a ferroelectric material provides the added benefit of nonvolatility as it can be used to store the applied V_{G} history. Namely, the V_{G} applied in step 1502 also serves to switch the polarization of the ferroelectric domains in the ferroelectric material 402. Alternatively, the ferroelectric domains of the ferroelectric material can be pre-aligned during fabrication of the memristive device, thereby eliminating the need for access to the gate terminal 112 during operation.

As described in detail above, applying the first voltage (i.e., gate voltage) to the gate terminal 112 serves to build up charge in the memristive material 102. Doing so lowers a threshold voltage (V_{TH}) of the memristive material via field effects. Namely, the V_{TH} of the memristive material 102 with applied V_{G} is lower than what the V_{TH} of the memristive material 102 would be without the applied V_{G}.

In step 1504, a second voltage is applied to one of the electrodes to program a resistance of the memristive material 102. Being that the electrodes are in direct contact with the memristive material 102, application of the second voltage will result in a current flow through the memristive material 102. For example, applying the second voltage to the second electrode 106 and third electrode 108 will result in a current flow between the second electrode 106/third electrode 108 and the first (bottom) electrode 104. Similarly, applying the second voltage to the source electrode 702 (see, e.g., FIG. 8) will result in a current flow through the memristive material 102 between the source electrode 702 and the drain electrode 704. However, the V_{TH} of the memristive material 102 has been lowered (in step 1502). Thus, the second voltage needed to program the memristive material 102 in step 1504 is lower than the voltage that would be needed had the V_{TH} of the memristive material 102 not been lowered.

Although illustrative embodiments of the present invention have been described herein, it is to be understood that the invention is not limited to those precise embodiments, and that various other changes and modifications may be made by one skilled in the art without departing from the scope of the invention.

What is claimed is:

1. A memristive device, comprising:
a memristive material;
multiple electrodes directly contacting the memristive material; and
a gate terminal separated from the memristive material by an electrical insulator.

2. The memristive device of claim 1, wherein the memristive material comprises a phase change material selected from the group consisting of: Sb₂Te₃, GeTe, Ge₂Sb₂Te₅, GaSb, Ge—Sb based alloys, and combinations thereof.

3. The memristive device of claim 1, where the memristive material comprises an organic semiconductor or a two-dimensional semiconductor.

4. The memristive device of claim 1, wherein the multiple electrodes comprise a first electrode, a second electrode and a third electrode each directly contacting the memristive material.

5. The memristive device of claim 4, wherein the first electrode directly contacts a bottom of the memristive material, and wherein the second electrode and the third electrode directly contact opposite sides of the memristive material.

6. The memristive device of claim 4, wherein the first electrode, the second electrode and the third electrode each directly contacts a bottom of the memristive material.

7. The memristive device of claim 4, further comprising:
an access transistor connected to the first electrode.

8. The memristive device of claim 7, further comprising:
a first word line connected to the gate terminal;
a bit line connected to the second electrode and the third electrode;
a source line connecting a source node of the access transistor to the first electrode; and
a second word line connected to a gate node of the access transistor.

9. The memristive device of claim 4, wherein the multiple electrodes comprise a source electrode and a drain electrode which directly contact opposite sides of the memristive material.

10. The memristive device of claim 1, wherein the electrical insulator comprises an oxide dielectric material.

11. The memristive device of claim 10, wherein the oxide dielectric material is selected from the group consisting of: SiOx, HfO₂, La₂O₃, HfLaO₂, HfZrO₂, HfAlO₂, TiO₂, ZrO₂, and combinations thereof.

12. The memristive device of claim 1, wherein the electrical insulator comprises a ferroelectric material.

13. The memristive device of claim 12, wherein the ferroelectric material is selected from the group consisting of: KNaC₄H₄O₆·4H₂O, Bi₄Ti₃O₂, BaTiO₃, Ba_{0.73}Sr_{0.27}TiO₃, PbZr₁₋ₓTiₓO₃, PbTiO₃, PbZrO₃, LiNbO₃, KNbO₃, PbBi₂Nb₂O₉, KH₂PO₄, C(NH₂)₃Al(SO₄)₂·6H₂O, SrBi₂Ta₂O₉, and combinations thereof.

14. The memristive device of claim 1, further comprising:
a selector cell comprising a selector material, wherein the gate terminal and the electrical insulator are shared across the memristive material and the selector material, and wherein the selector material is a chalcogenide material selected from the group consisting of: GeSe, SiTe, SiSe, and combinations thereof.

15. A system, comprising:
a unit cell having multiple memristive devices, wherein each of the multiple memristive devices comprises a memristive material, multiple electrodes directly contacting the memristive material, and a gate terminal separated from the memristive material by an electrical insulator; and
a gate word line connected to the gate terminal of each of the multiple memristive devices in the unit cell.

16. The system of claim 15, wherein each of the multiple memristive devices in the unit cell further comprises an access transistor connected to one of the multiple electrodes, and wherein the system further comprises:
a transistor word line connected to a gate node of the access transistor of each of the multiple memristive devices in the unit cell.

17. A method for operating a memristive device, the method comprising:
applying a gate voltage to the memristive device, wherein the memristive device comprises a memristive material, multiple electrodes directly contacting the memristive material, and a gate terminal separated from the memristive material by an electrical insulator, and wherein the gate voltage is applied to the gate terminal to build up charge in the memristive material, thereby lowering a threshold voltage of the memristive material via field effects.

18. The method of claim 17, wherein the multiple electrodes comprise a first electrode, a second electrode and a third electrode each directly contacting the memristive material, wherein the gate voltage comprises a first voltage that is applied to the gate terminal, and wherein the method further comprises:
applying a second voltage to the second electrode and the third electrode to program a resistance of the memristive material, wherein the second voltage results in a current flow through the memristive material between the second electrode, the third electrode and the first electrode.

19. The method of claim 18, wherein the electrical insulator comprises an oxide dielectric material.

20. The method of claim 18, wherein the electrical insulator comprises a ferroelectric material, and wherein the method further comprises:
switching a polarization of ferroelectric domains in the ferroelectric material via the gate voltage.
